(19) United States
(12) Patent Application Publication
(10) Pub. No.: US 2026/0090419 A1
(43) Pub. Date: Mar. 26, 2026

(54) METHOD AND APPARATUS FOR PROVIDING ELECTRONIC DEVICE

(71) Applicant: Samsung Display Co., Ltd., Yongin-si (KR)

(72) Inventors: Seokgi Baek, Yongin-si (KR); Incheol Song, Yongin-si (KR); Eunchul Shin, Yongin-si (KR); Duhyun Kim, Yongin-si (KR); Kihoon Lee, Yongin-si (KR); Taejin Jang, Yongin-si (KR)

(21) Appl. No.: 19/243,784

(22) Filed: Jun. 20, 2025

(30) Foreign Application Priority Data
Sep. 26, 2024 (KR) 10-2024-0131091

(51) Int. Cl. H01L 23/498; G09G 3/20; G09G 3/3233; H10K 59/131; H10K 59/95

(52) U.S. Cl. CPC H10W 70/65; G09G 3/2096; H10K 59/131; H10K 59/95; G09G 3/3233; G09G 2300/0819; G09G 2300/0842; G09G 2300/0861

(57) ABSTRACT

An apparatus for providing an electronic device includes a connection portion including terminals at which the apparatus is connected to a display panel of the electronic device, a circuit board from which an electrical signal is provided to the display panel and to which an electrical signal generated from the display panel is provided, and connection members each electrically connecting the connection portion to the circuit board. The connection members include a first connection member having a first wire through which a first electrical signal passes, and a second connection member having a second wire through which a second electrical signal passes. The first connection member, the second connection member and the circuit board overlap each other along a thickness direction of the circuit board to define an overlapping area. Within the overlapping area, the first wire and the second wire are non-overlapping.

This application claims priority to Korean Patent Application No. 10-2024-0131091 filed Sep. 26, 2024, and all the benefits accruing therefrom under 35 U.S.C. § 119, the disclosure of which is incorporated by reference herein in its entirety.

### BACKGROUND

### 1. Field

One or more embodiments relate to a method and an apparatus. More particularly, one or more embodiments relate to a method and an apparatus for manufacturing (or providing) a display device.

### 2. Description of the Related Art

Mobility based electronic devices have been widely used. In addition to small electronic devices such as mobile phones, tablet personal computers (PCs) have recently been widely used as mobile electronic devices.

In order to support various functions, such mobile electronic devices include a display panel for providing a user with visual information, such as images or videos. As other parts for driving the display panel have become smaller, the proportion of volume occupied by display panels in electronic devices has been gradually increasing, and a structure of the electronic device which is capable of being bent from a flat state to have a certain angle has also been developed.

### SUMMARY

In general, various tests may be performed to check the operation of a display panel, such as during a method of providing (or manufacturing) an electronic device including the display panel. In this regard, electrical signals applied to the display panel may have direct (electrical) current and alternating (electrical) current forms and thus may affect or influence each other. As a result, at least one of the electrical signals applied to the display panel may include noise or at least one of the electrical signals generated from the display panel may include noise, which may prevent precise measurement of an operation of the display panel. One or more embodiments include a method and an apparatus for manufacturing (or providing) a display device including a display panel, allowing precise measurement and inspection thereof.

Additional aspects will be set forth in part in the description which follows and, in part, will be apparent from the description, or may be learned by practice of the presented embodiments of the disclosure.

According to one or more embodiments, an apparatus for manufacturing (or providing) a display device and/or a display panel includes a connection portion including a plurality of terminals connected to a display panel, a first connection member connected to the connection portion and including a plurality of first wires through which a signal applied to the display panel or a signal generated from the display panel passes, and a second connection member connected to the connection portion and including a plurality of second wires through which a signal applied to the display panel or a signal generated from the display panel passes, where at least a portion of the first connection member and at least a portion of the second connection member overlap each other in a plan view, and a portion of at least one of the plurality of first wires and a portion of at least one of the plurality of second wires are arranged at different positions.

In an embodiment, a first width of a planar shape of the first connection member may be greater than a second width of a planar shape of the second connection member.

In an embodiment, the signal which passes through the first wires may be in a form of alternating current, and the signal which passes through the second wires may be in a form of direct current.

In an embodiment, a width of at least a portion of a planar shape of the first connection member may vary depending on a length direction of the first connection member.

In an embodiment, at least one of the plurality of first wires may be at least partially bent.

In an embodiment, at least one of the plurality of first wires may include a 1st-1 wire inclined in a direction away from a center of the first connection member, a 1st-2 wire connected to the 1st-1 wire and arranged parallel to a length direction of the first connection member, and a 1st-3 wire connected to the 1st-2 wire and inclined in a different direction from the 1st-1 wire.

In an embodiment, the first connection member may include an opening between some of the plurality of first wires and others of the plurality of first wires.

In an embodiment, in a plan view, the plurality of second wires may be arranged between some of the plurality of first wires and others of the plurality of first wires.

In an embodiment, a distance between one of the plurality of second wires and another one of the plurality of second wires which are adjacent to each other may be 20 μm or greater.

In an embodiment, the first connection member may include a shield layer on a surface of the first connection member which faces the second connection member.

According to one or more embodiments, a method of manufacturing a display device includes transmitting a first signal and a second signal to a display panel through a plurality of first wires of a first connection member and a plurality of second wires of a second connection member, and receiving a signal generated from the display panel through the plurality of second wires through the plurality of second wires, where at least a portion of the first connection member and at least a portion of the second connection member overlap each other in a plan view, and a portion of at least one of the plurality of first wires and a portion of at least one of the plurality of second wires are arranged at different positions in a plan view.

In an embodiment, a first width of a planar shape of the first connection member may be greater than a second width of a planar shape of the second connection member.

In an embodiment, the signal which passes through the first wires may be in a form of alternating current, and the signal which passes through the second wires may be in a form of direct current.

In an embodiment, a width of at least a portion of a planar shape of the first connection member may vary depending on a length direction of the first connection member.

In an embodiment, at least one of the plurality of first wires may be at least partially bent.

In an embodiment, at least one of the plurality of first wires may include a 1st-1 wire inclined in a direction away from a center of the first connection member, a 1st-2 wire connected to the 1st-1 wire and arranged parallel to a length direction of the first connection member, and a 1st-3 wire connected to the 1st-2 wire and inclined in a different direction from the 1st-1 wire.

In an embodiment, the first connection member may include an opening between some of the plurality of first wires and others of the plurality of first wires.

In an embodiment, in a plan view, the plurality of second wires may be arranged between some of the plurality of first wires and others of the plurality of first wires.

In an embodiment, a distance between one of the plurality of second wires and another one of the plurality of second wires which are adjacent to each other may be 20 μm or greater.

In an embodiment, the first connection member may include a shield layer on a surface of the first connection member which faces the second connection member.

These general and specific embodiments may be implemented by using a system, a method, a computer program, or any combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an apparatus for manufacturing (or providing) a display device, according to an embodiment;

FIG. 2 is a schematic cross-sectional view of a probe terminal of a probe block shown in FIG. 1;

FIG. 3 is a schematic plan view of a first connection member and a second connection member shown in FIG. 1;

FIG. 4 is a schematic cross-sectional view of the first connection member and the second connection member shown in FIG. 3;

FIG. 5 is a schematic plan view of a first connection member of an apparatus for manufacturing a display device, according to an embodiment;

FIG. 6 is a schematic plan view of a first connection member of an apparatus for manufacturing a display device, according to an embodiment;

FIG. 7 is a schematic plan view of a first connection member of an apparatus for manufacturing a display device, according to an embodiment;

FIGS. 8A and 8B are schematic plan views of a display panel according to an embodiment;

FIG. 9 is an equivalent circuit diagram showing a pixel according to an embodiment; and

FIG. 10 is an enlarged cross-sectional view of the display panel taken along a line A-A′ of FIG. 8A or 8B.

FIG. 11 is a block diagram illustrating an electronic device according to an embodiment of the present disclosure.

FIG. 12 is a schematic view of electronic devices according to embodiments of the present disclosure.

### DETAILED DESCRIPTION

Reference will now be made in detail to embodiments, examples of which are illustrated in the accompanying drawings, where like reference numerals refer to like elements throughout. In this regard, an embodiments may have different forms and should not be construed as being limited to the descriptions set forth herein. Accordingly, the embodiments are merely described below, by referring to the figures, to explain aspects of the present description.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, an embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted. Within the Figures and the text of the disclosure, a reference number indicating a singular form of an element may also be used to reference a plurality of the element.

While such terms as “first” and “second” may be used to describe various elements, such elements must not be limited to the above terms. The above terms are used only to distinguish one element from another. For example, 1st-1, 1st-2, 1st-3, etc. may be used to index a first, second, third, etc. occurrence of an element.

The terminology used herein is for the purpose of describing particular embodiments only and is not intended to be limiting. The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being related to another layer such as being “on” another layer, region, or element, it may be directly or indirectly on the other layer, region, or element. That is, for example, intervening layers, regions, or elements may be present. In contrast, when a layer, region, or element is referred to as being related to another layer such as being “directly on” another layer, region, or element, no other layer, region, or element is present therebetween.

Sizes of elements in the drawings may be exaggerated or reduced for convenience of explanation. For example, since sizes and thicknesses of elements in the drawings are arbitrarily illustrated for convenience of description, the following embodiments are not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

When an embodiment may be implemented differently, a certain process order may be performed differently from the described order. For example, two consecutively described processes may be performed substantially at the same time or performed in an order opposite to the described order.

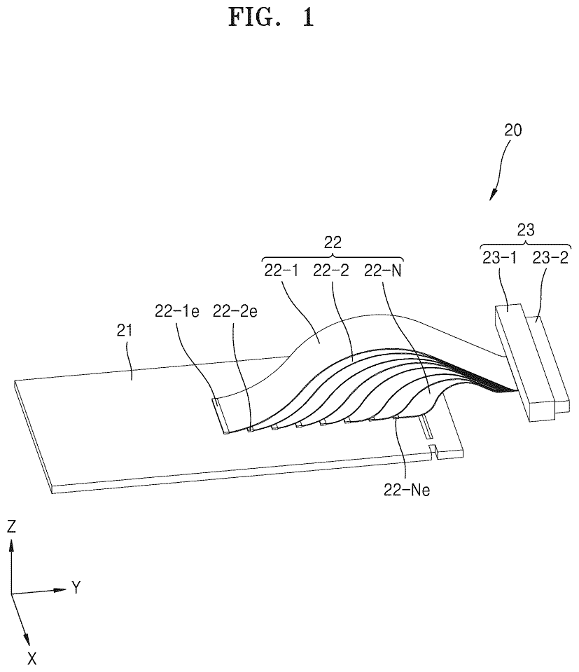

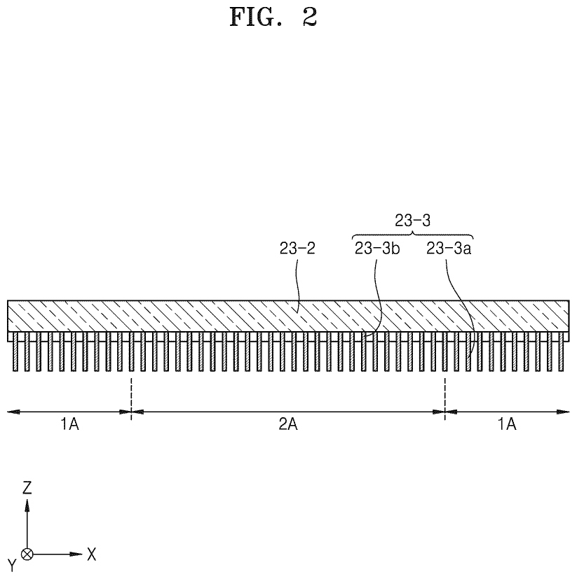

FIG. 1 is a schematic perspective view of an apparatus 20 for manufacturing (or providing) a display device, according to an embodiment. FIG. 2 is a schematic cross-sectional view of a probe terminal of a probe block 23 shown in FIG. 1. The apparatus 20 may be an inspection tool which measures or verifies operation of an electronic device.

Referring to FIG. 1, the apparatus 20 for manufacturing a display device may include a test circuit board 21 as a circuit board, a connection member 22, and the probe block 23 as a connection portion of the apparatus 20.

The test circuit board 21 may be connected to a signal generator (not shown) separate from the test circuit board 21 and configured to generate a signal (e.g., an electrical signal, a test signal) which is provided to test an electronic device like a display panel 10, and to a signal analyzer (not shown) which is configured to analyze a signal generated from a display panel 10 (not shown) for determining an operation or function of the display panel 10. In an embodiment, the signal generator and the signal analyzer may be integrally formed with the test circuit board 21.

The connection member 22 may connect (e.g., electrically connect) the test circuit board 21 and the probe block 23 to each other. In this regard, the connection member 22 may include a plurality of connection members 22, and the plurality of connection members 22 may be spaced apart from each other in a third direction or a thickness direction of the apparatus 20 (e.g., a Z direction of FIG. 1). The plurality of connection members 22 may be spaced apart from each other in a direction along the test circuit board 21, like a planar direction defined by directions crossing each other and intersecting the thickness direction. Each connection member 22 may be configured to transmit various signals as a an electrical signal, a test signal, etc. For example, one of the plurality of connection members 22 may be configured to transmit an alternating (electrical) current signal. In addition, another one of the plurality of connection members 22 may be configured to transmit a direct (electrical) current signal.

A case where the plurality of connection members 22 include a first connection member 22-1, a second connection member 22-2, . . . , and an Nth connection member 22-N in order in a direction from the outside of the test circuit board 21 to the inside thereof will be mainly described below for convenience. In this regard, N is a natural number of 3 or greater. In addition, the first connection member 22-1 may be configured to transmit an alternating current signal, and the second connection member 22-2, . . . , and the Nth connection member 22-N may be configured to transmit a direct current signal.

The first connection member 22-1 may be arranged on the outermost (or upper) side of the test circuit board 21 in consideration of the third direction. The second connection member 22-2 may be arranged between the first connection member 22-1 and the test circuit board 21. In addition, the Nth connection member 22-N may be arranged between the second connection member 22-2 and the test circuit board 21. In the above case, each of the first connection member 22-1, the second connection member 22-2, . . . , and the Nth connection member 22-N may lengthwise extend from the probe block 23 and may be at least partially bent along the length direction. Thus, a space (or volume) occupied by each of the first connection member 22-1, the second connection member 22-2, . . . , and the Nth connection member 22-N within the apparatus 20 may be reduced, such that even when the height in the third direction between the probe block 23 and the test circuit board 21 is different, the probe block 23 and the test circuit board 21 may remain connected to each other.

In this regard, the first connection member 22-1, the second connection member 22-2, . . . , and the Nth connection member 22-N may be flexible printed circuit boards (FPCBs) each as flexible circuit boards. In addition, the first connection member 22-1, the second connection member 22-2, . . . , and the Nth connection member 22-N may separately and individually have a first connection member connector 22-1e, a second connection member connector 22-2e, . . . , and an Nth connection member connector 22-Ne, which are each connected to the test circuit board 21, at an end of a connection member, respectively. The connection member connector may be disposed at a distal end of a respective connection member. In this regard, the first connection member connector 22-1e, the second connection member connector 22-2e, . . . , and the Nth connection member connector 22-Ne may be arranged in a line in a direction along the test circuit board 21, such as along a length thereof. For example, the first connection member connector 22-1e, the second connection member connector 22-2e, . . . , and the Nth connection member connector 22-Ne may be arranged in a line in a second direction (e.g., a Y direction of FIG. 1) among planar directions. In this case, in a plan view, the first connection member 22-1, the second connection member 22-2, . . . , and the Nth connection member 22-N may overlap one another in the third direction.

The probe block 23 may include a first body 23-1, a second body 23-2, and the probe terminal portion 23-3. The first body 23-1 and the second body 23-2 may be connected to each other to provide a single body and may provide a space for connecting the probe terminal portion 23-3 to each connection member 22. For example, separate wiring (not shown) may be arranged between the first body 23-1 and the second body 23-2 to respectively connect the probe terminal portion 23-3 to each connection member 22. In an embodiment, a separate connection film (not shown) may be arranged between the first body 23-1 and the second body 23-2, and the connection film may also respectively connect the probe terminal portion 23-3 to each connection member 22. In this case, the connection film may be provided in correspondence with the number of connection members 22. A case where the probe terminal portion 23-3 is connected to each connection member 22 through separate wiring arranged inside the first body 23-1 and the second body 23-2 will be mainly described below for convenience.

The second body 23-2 may be arranged in correspondence with a pad portion (not shown) of a display panel 10, a display device, an electronic device, etc. (not shown). In this regard, the second body 23-2 may be coupled (e.g., electrically, physically, mechanically, etc.) to the pad portion of the display panel 10 or may be arranged on the pad portion. In an embodiment, the display panel 10 may have the pad portion connected to a separate FPCB different from the apparatus 20, and may be arranged on the separate FPCB in correspondence with the same and be connected to the probe terminal portion 23-3 of the apparatus 20. In an embodiment, the display panel 10 may have the pad portion connected to a display circuit board described below, and the probe terminal portion 23-3 may be connected to the display circuit board. That is, the apparatus 20 may be connected to an electronic device to be tested, at the pad portion of such electronic device.

The probe terminal portion 23-3 may include a plurality of contact portions (not denoted). In this regard, each of the contact portions may have or be defined by a pin-shaped probe terminal and/or a groove shape, and thus may be electrically connected to the display panel 10, such as at the pad portion thereof. A case where the contact portion includes a probe terminal will be mainly described below for convenience.

A plurality of probe terminals 23-3a and 23-3b may be arranged in the probe terminal portion 23-3, such as along the second body 23-2. In this regard, the plurality of probe terminals 23-3a and 23-3b may be divided into two areas (e.g., planar areas) along a length of the probe block 23 and arranged therein. For example, the plurality of probe terminals 23-3a and 23-3b may include a first probe terminal 23-3a arranged in a first area 1A and a second probe terminal 23-3b arranged in a second area 2A which is adjacent to the first area 1A along the length of the probe block 23. In this regard, an alternating current signal may be transmitted through the first probe terminal 23-3a arranged in the first area A1. A direct current signal may be transmitted through the second probe terminal 23-3b arranged in the second area A2. That is, the first probe terminal 23-3a of the plurality of probe terminals 23-3a and 23-3b, through which an alternating current signal is transmitted, may be arranged at the periphery of the probe terminal portion 23-3, and the second probe terminal 23-3b through which a direct current signal is transmitted may be arranged in a central area of the probe terminal portion 23-3 which is further from an end (e.g., periphery) of the second body 23-2. Thus, when a signal is transmitted through each probe terminal 23-3a and 23-3b, such as at a same time or simultaneously, the influence of an alternating current signal on a direct current signal may be reduced.

According to the above operation of the apparatus 20 for manufacturing (or providing) a display device or an electronic device, the probe terminal portion 23-3 may be connected to the display panel 10 of such display device or electronic device. In this regard, the probe terminal portion 23-3 may be connected to the display panel 10 in various ways. For example, the probe terminal portion 23-3 may be arranged on a position-changing apparatus for changing a position thereof, for example, raising or lowering the probe terminal portion 23-3, and the probe terminal portion 23-3 may selectively come into contact with the pad portion of the display panel 10 according to an operation of the position-changing apparatus. In an embodiment, the second body 23-2 may be coupled to the pad portion of the display panel 10. In this regard, the pad portion may include a separate structure (not shown) at which the display panel 10 is coupled to the second body 23-2. In an embodiment, a separate adhesive member including a conductive material may be arranged between the second body 23-2 and the pad portion, and the probe terminal portion 23-3 and the pad portion may be connected to each other through the adhesive member. In an embodiment, the display panel 10 may be connected to a display controller (not shown) including a separate display circuit board, and the probe terminal may be connected to the display controller. In this regard, a method in which the probe terminal is connected to the display controller may be similar to the above method in which the probe terminal is connected to the pad portion of the display panel 10.

A case where the probe terminal comes into direct contact with the pad portion will be mainly described below for convenience. In this regard, terminals (e.g., a test terminal provided in plural including test terminals) are arranged in the pad portion of the electronic device to be inspected or tested, and each probe terminal of the apparatus 20 may come into direct contact with each of the test terminals. As being in contact, elements may form an interface (e.g., a physical interface) therebetween.

When each probe terminal of the apparatus 20 comes into contact with each of the (test) terminals of the respective electronic device (e.g., the display panel 10), the signal generator may be configured to generate a signal and apply the signal to the display panel 10. In this regard, the signal may include at least one of a variety of signals for driving the display panel 10, such as a bias control signal, an emission control signal, a clock signal, a data signal, a bias voltage, an initialization voltage, and a driving voltage. In this regard, the bias control signal, the emission control signal, and the clock signal may be alternating current signals, and the data signal, the bias voltage, the initialization voltage, and the driving voltage may be direct current signals. In this case, the bias control signal, the emission control signal, and the clock signal may be transferred through the first connection member 22-1, and the data signal, the bias voltage, the initialization voltage, and the driving voltage may be transferred through one of the second connection member 22-2 to the Nth connection member 22-N. In this regard, each of the data signal, the bias voltage, the initialization voltage, and the driving voltage may be transferred through each of the second connection member 22-2 to the Nth connection member 22-N.

In the above case, the signal generator may vary a level of a first initialization voltage of the initialization voltage. Thus, a change in a second initialization voltage of the initialization voltage may be detected by the signal analyzer, and thus, it may be determined whether there is an abnormality in an operation of the display panel 10. In particular, the signal analyzer may detect a change in the amount of current of a first transistor of each sub-pixel of the display panel 10 by analyzing the change in the second initialization voltage.

In this case, the apparatus 20 for manufacturing (or testing) a display device or other electronic device may reduce the influence of an alternating current signal on a direct current signal. In particular, the influence of variation of the alternating current signal on a tiny change in the second initialization voltage may be reduced, and thus, a degree of variation of the second initialization voltage may be precisely measured. In particular, in the above case, a change in current which may be measured through a change in the second initialization voltage may be expanded to the range of picoampere (pA).

Accordingly, the apparatus 20 for manufacturing a display device and a method of manufacturing a display device which uses the apparatus 20 may allow the display panel 10 to be precisely tested. In addition, the apparatus 20 for manufacturing a display device and a method of manufacturing a display device which uses the apparatus 20 may allow a small change in electrical current to be accurately detected.

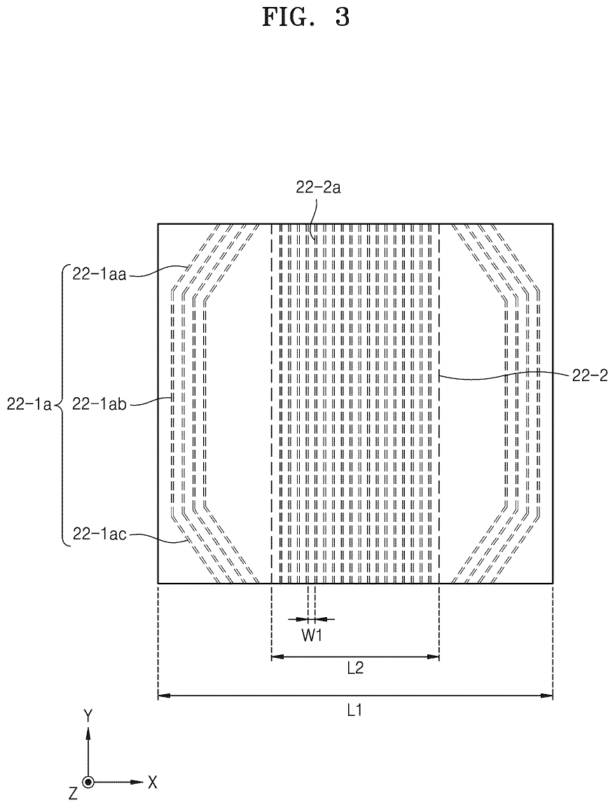

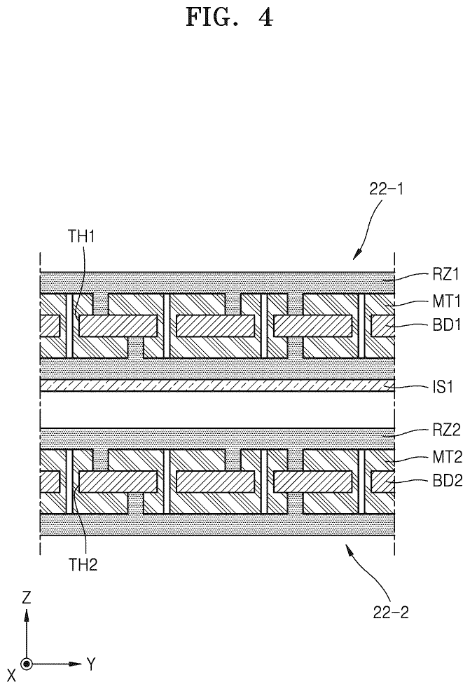

FIG. 3 is a schematic plan view of the first connection member 22-1 and the second connection member 22-2 shown in FIG. 1. FIG. 4 is a schematic cross-sectional view of the first connection member 22-1 and the second connection member 22-2 shown in FIG. 3.

Referring to FIGS. 3 and 4, the first connection member 22-1 and the second connection member 22-2 may be stacked on each other, that is, along the thickness direction of the test circuit board 21. In this regard, the first connection member 22-1 may include a first wire 22-1a through which a signal passes, and the second connection member 22-2 may include a second wire 22-2a through which a signal passes. In this regard, the first wire 22-1a may include a first resin layer BD1, a first metal layer MT1 and a first cover layer RZ1. A shield layer IS1 may be disposed on the first connection member 22-1.

Within the first connection member 22-1, the first resin layer BD1 and the first metal layer MT1 may be provided as a single layer (e.g., in a single number) or in plural as a plurality of layers (e.g., in plural number). When one single first resin layer BD1 and one single first metal layer MT1 are provided, the first metal layer MT1 may be arranged on the first resin layer BD1, and the first metal layer MT1 may constitute the first wire 22-1a. In an embodiment, when a plurality of first resin layers BD1 and a plurality of first metal layers MT1 are provided, the plurality of first resin layers BD1 and the plurality of first metal layers MT1 may be alternately stacked on each other, and each first metal layer MT1 may constitute one first wire 22-1a. In addition, each first metal layer MT1 may constitute the first wire 22-1a as first metal layers MT1 which are adjacent to each other in a thickness direction of the first resin layer BD1 are interconnected. In this regard, the first metal layers MT1 may be connected to each other through a first through hole TH1 penetrating the first resin layer BD1. A separate metal may be filled in the first through hole TH1, or a portion of the first metal layer MT1 may extend into the first through hole TH1. A case where the first metal layer MT1 and the first resin layer BD1 are provided in a plurality of numbers and some of the plurality of first metal layers MT1 are interconnected to constitute one first wire 22-1a will be mainly described below for convenience.

The shield layer IS1 may be arranged under the first connection member 22-1. The first cover layer RZ1 may shield the first metal layer MT1. In this regard, the first cover layer RZ1 may be arranged at the top and bottom of the first connection member 22-1. The shield layer IS1 may be arranged between a portion of the first connection member 22-1 and the second connection member 22-2, and thus, a signal passing through the first wire 22-1a may not affect a signal passing through the second wire 22-2a. The shield layer IS1 may include an electromagnetic interference (EMI) shielding material. Here, along the thickness direction, the first connection member 22-1 includes a shield layer IS1 between the second connection member 22-2 and a remaining thickness portion of the first connection member 22-1.

The second connection member 22-2 may include a second resin layer BD2, a second metal layer MT2, a second cover layer RZ2 and a second through hole TH2. In this regard, the second resin layer BD2, the second metal layer MT2, the second cover layer RZ2 and the second through hole TH2 are the same as or similar to the first resin layer BD1, the first metal layer MT1, the first cover layer RZ1 and the first through hole TH1 described above, and thus, a detailed description thereof is omitted.

The first connection member 22-1 and the second connection member 22-2 may be separated and spaced apart from each other along the thickness direction of the connection members. In this regard, the alternating current signal described above may pass through the first wire 22-1a, and the direct current signal may pass through the second wire 22-2a. In this regard, the second connection member 22-2 may be provided in plural to include a plurality of second connection members 22-2. All of the plurality of second connection members 22-2 may be arranged under the first connection member 22-1. Thus, when a signal passing through the first wire 22-1a varies with time, variation of a signal passing through the second wire 22-2a due to the signal passing through the first wire 22-1a may be reduced.

The first wire 22-1a and the second wire 22-2a may each be provided in plural to include a plurality of first wires 22-1a and a plurality of second wires 22-2a, respectively. In this regard, a (first) portion of at least one of the plurality of first wires 22-1a and a (first) portion of at least one of the plurality of second wires 22-2a may not overlap each other. For example, another portion of the first wire 22-1a and another portion of the second wire 22-2a may cross or overlap each other. In this regard, the overlapping portion of the first wire 22-1a and the second wire 22-2a may have a minimal overlapping area such as to form a dot in the plan view or may be very short or small in planar dimension.

In an embodiment, the plurality of first wires 22-1a and the plurality of second wires 22-2a may not overlap each other at all in a plan view. For example, the plurality of second wires 22-2a may be arranged between some of the plurality of first wires 22-1a and others of the plurality of first wires 22-1a. That is, the plurality of first wires 22-1a may be divided into two groups, and the plurality of second wires 22-2a may be arranged between the two groups of the plurality of first wires 22-1a. For example, FIG. 3 shows a first group of the first wires and a second group of the first wires among the plurality of first wires 22-1a, while a group of second wires among and the plurality of second wires 22-2a is arranged between the two groups of the first wires, along a width direction of the connection members. Here, the first connection member 22-1 includes the first wire provided in plural including first wires at opposing sides of the first connection member 22-1 (e.g., opposing sides along the X direction), and the second wire between the first wires.

In the plan view, one of the plurality of first wires 22-1a may be at least partially bent, that is, may have at least one bend along a length of the first wire. For example, the first wire 22-1a may include a 1st-1 wire 22-1aa (e.g., a first wire portion or 1st-1 wire portion) arranged lengthwise diagonally with respect to a length direction of the second wire 22-2a and connected to a first probe terminal. The first wire 22-1a may include a 1st-2 wire 22-1ab (e.g., a second wire portion or 1st-2 wire portion) connected to the 1st-1 wire 22-1aa, arranged lengthwise parallel to the length direction of the second wire 22-2a, and being straight or linear in shape. The first wire 22-1a may include a 1st-3 wire 22-1ac (e.g., a third wire portion or 1st-3 wire portion) connected to the 1st-2 wire 22-1ab and arranged lengthwise diagonally with respect to the length direction of the second wire 22-2a. In this regard, an extending direction of the 1st-3 wire 22-1ac may be different from an extending direction of the 1st-1 wire 22-1aa. The 1st-3 wire 22-1ac may be connected to a respective connection member connector arranged at an end of the first connection member 22-1.

Each second wire 22-2a may be straight, that is, may exclude a bend. The plurality of second wires 22-2a may be spaced apart from each other by a certain. In this regard, a distance W1 as a spacing between each second wire 22-2a and another second wire 22-2a may be about 20 micrometers (μm) or greater, that is, equal to or greater than about 20 micrometers. When the distance W1 between second wires 22-2a adjacent to each other is about 20 μm, leakage current between adjacent second wires 22-2a or between an outermost one of the second wires 22-2a and the first wire 22-1a adjacent to the outermost one may be minimum. Thus, influence between a signal passing through the second wire 22-2a and a signal passing through the first wire 22-1a may be minimized. On the other hand, when the distance W1 between each second wire 22-2a and another one of the second wire 22-2a is less than 20 μm, leakage current between adjacent second wires 22-2a or between the first wire 22-1a and the outermost second wire 22-2a may undesirably gradually increase.

In an embodiment, the apparatus 20 for providing an electronic device includes a connection portion (e.g., the probe block 23) including probe terminals at which the apparatus 20 is connected to a display panel 10 of the electronic device, a circuit board (e.g., the test circuit board 21) from which an electrical signal is provided to the display panel 10 and to which an electrical signal generated from the display panel 10 is provided, and connection members each electrically connecting the connection portion to the circuit board, the connection members including a first connection member 22-1 including a first wire 22-1a through which a first electrical signal passes between the connection portion and the circuit board, and a second connection member 22-2 through 22-N including a second wire 22-2a through which a second electrical signal passes between the connection portion and the circuit board. Referring to FIGS. 1 and 3, for example, the first connection member 22-1, the second connection member 22-2 through 22-N and the circuit board overlap each other along a thickness direction of the circuit board (e.g., the Z direction) to define an overlapping area (e.g., a planar area common to each of the first connection member 22-1, the second connection member 22-2 through 22-N and the circuit board). Within the overlapping area, the first wire 22-1a and the second wire 22-2a are non-overlapping.

In an embodiment, the first electrical signal includes alternating electrical current, and the second electrical signal includes direct electrical current.

A first width L1 of the first connection member 22-1 and a second width L2 of the second connection member 22-2 may be different from each other. For example, the first width L1 may be greater than the second width L2. In this regard, the first width L1 and the second width L2 may be measured in a width direction perpendicular to a length direction of the first connection member 22-1 or to a length direction of the second connection member 22-2. Here, the connection members each extend in a direction (Y direction) from the connection portion to the circuit board, and in a direction (X direction) which crosses the length direction, a width of the first connection member 22-1 is greater than a width of the second connection member 22-2.

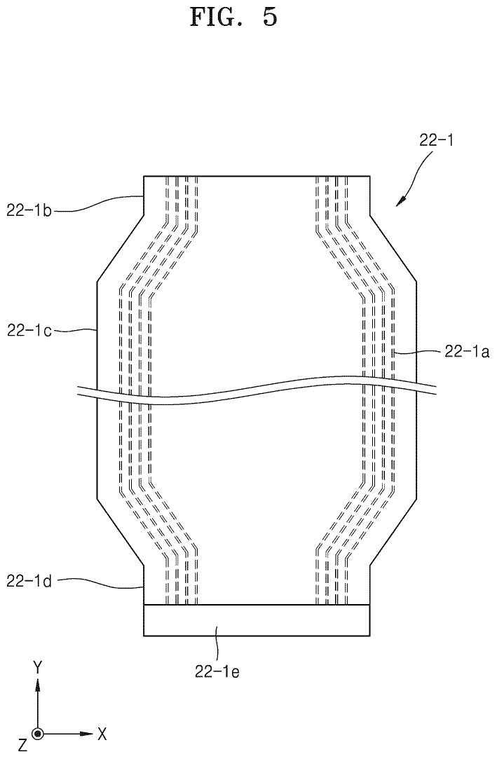

FIG. 5 is a schematic plan view of a first connection member 22-1 of an apparatus 20 for manufacturing a display device, according to an embodiment.

Referring to FIG. 5, an apparatus 20 (not shown) for manufacturing a display device may be the same as or similar to that described above with reference to FIGS. 1 and 2. The first connection member 22-1 of the apparatus 20 for manufacturing a display device will be described below in more detail for convenience.

The first connection member 22-1 may include a first portion 22-1b, a second portion 22-1c, and a third portion 22-1d. Each of these portions may be a planar area of the first connection member 22-1, such as having a width along the X direction and a length along the Y direction. In this regard, a width of the first portion 22-1b may be different from a width of the second portion 22-1c. In addition, a width of the second portion 22-1c may be different from a width of the third portion 22-1d. For example, a width of the first portion 22-1b and a width of the third portion 22-1d may be less than a width of the second portion 22-1c. In this regard, the width of the first portion 22-1b and the width of the second portion 22-1c may be the same as each other. In addition, a width of the first connection member 22-1 may increase in a direction from the first portion 22-1b to the second portion 22-1c and may decrease in a direction from the second portion 22-1c to the third portion 22-1d. In the above case, the first connection member connector 22-1e may be connected to the first connection member 22-1 at the third portion 22-1d, and the first connection member connector 22-1e may be connected to a test circuit board 21 (not shown).

The first connection member 22-1 may include the first wire 22-1a. In this regard, the first wire 22-1a is the same as or similar to that described above with reference to FIGS. 3 and 4, and thus, a detailed description thereof is omitted.

Referring to FIG. 4, the stack of layers within a respective connection member may form a body of such connection member. One or more the layers may define a portion (or an entirety of) an outer edge of the body.

In FIG. 5, for example, the outer edge of the body of the first connection member 22-1 may be extended parallel to wire portions of the first wire 22-1a. An extension direction of the outer edge may change directions along the Y direction, at bends in the body. Such bends or changes in direction may occur at a corner or point, without being limited thereto. Although not shown, at least one of a part where the first portion 22-1b and the second portion 22-1c are connected to each other (e.g., a bend) and a part where the second portion 22-1c and the third portion 22-1d are connected to each (e.g., a bend) other may be rounded instead of being a corner or point change in direction. Here, the connection members each extend in a direction from the connection portion to the circuit board, and a width of the first connection member 22-2 in a direction which crosses the length direction varies along the length direction of the first connection member 22-1.

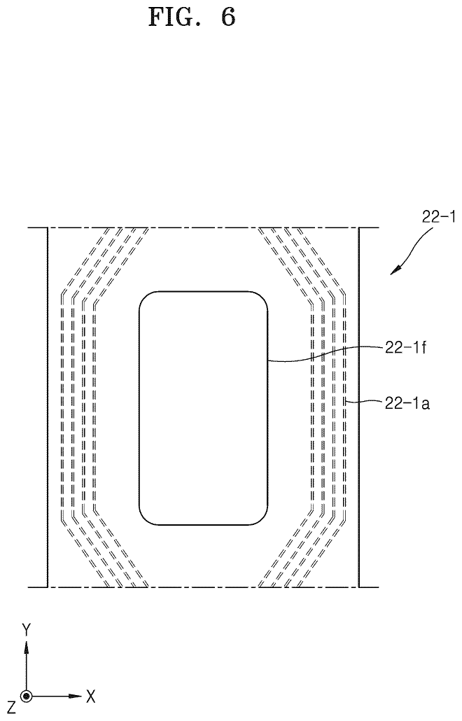

FIG. 6 is a schematic plan view of a first connection member 22-1 of an apparatus 20 for manufacturing a display device, according to an embodiment.

Referring to FIG. 6, an apparatus 20 (not shown) for manufacturing a display device may be the same as or similar to that described above with reference to FIGS. 1 and 2. The first connection member 22-1 of the apparatus 20 for manufacturing a display device will be described below in more detail for convenience.

The first connection member 22-1 may include the first wire 22-1a and an opening 22-1f which is defined in the body of the first connection member 22-1. The first wire 22-1a is the same as or similar to that described above with reference to FIGS. 3 and 4, and thus, a detailed description thereof is omitted.

The opening 22-1f may be arranged in a central portion of the first connection member 22-1. The opening 22-1f may be spaced apart from outer edges opposing each other in the width direction. In this regard, the opening 22-1f may be in the form of a hole completely penetrating a thickness of the body or a groove partially recessed into the thickness of the body, such that the body has a minimal thickness at the opening 22-1f. A planar shape of the opening 22-1f may be an enclosed shape to provide an enclosed opening defined by portions of the body. Here, the first connection member 22-1 includes the first wire provided in plural including first wires, and an opening 2-1f which is defined in the first connection member 22-1 and between the first wires.

The opening 22-1f may not only reduce the load on the first connection member 22-1 but also increase flexibility of the first connection member 22-1. Although not shown, the opening 22-1f may at least partially overlap the second wire 22-2a shown in FIG. 3. That is, a width of the opening 22-1f may be the same as a width of an area where the plurality of second wires 22-2a are arranged or may be greater than a width of an area where the plurality of second wires 22-2a are arranged.

Although not shown, a width of the first connection member 22-1 may be similar to that shown in FIG. 5.

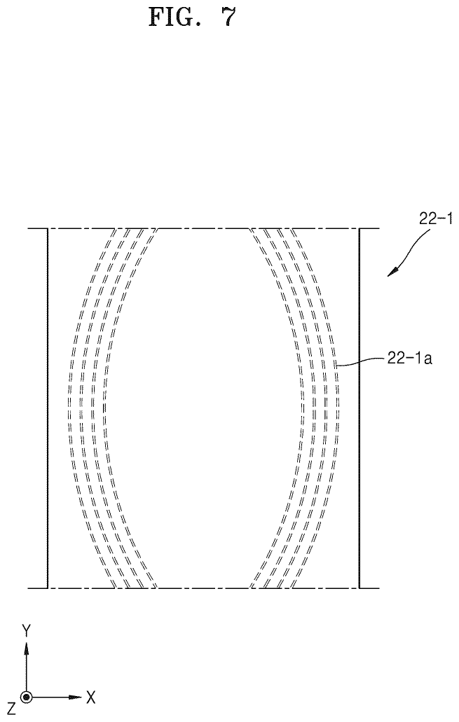

FIG. 7 is a schematic plan view of a first connection member 22-1 of an apparatus 20 for manufacturing a display device, according to an embodiment.

Referring to FIG. 7, an apparatus 20 (not shown) for manufacturing a display device may be the same as or similar to that described above with reference to FIGS. 1 and 2. The first connection member 22-1 of the apparatus 20 for manufacturing a display device will be described below in more detail for convenience.

The first connection member 22-1 may include a plurality of first wires 22-1a. Two groups of the first wires 22-1a may be respectively disposed at opposing sides of the body of the first connection member 22-1. Instead of a linear extension, a planar shape of at least one of the plurality of first wires 22-1a may be round or curved along the length direction of the body. In this regard, the first wire 22-1a which is curved may have one radius of curvature or a plurality of radii of curvature along the length direction of the body. The plurality of radii of curvature may include more than one of an inflection point where extension directions of the first wire 22-1a change. The plurality of first wires 22-1a may not overlap the second wire 22-2a as shown in FIG. 3.

Although not shown, a width of the first connection member 22-1 may be similar to that shown in FIG. 5.

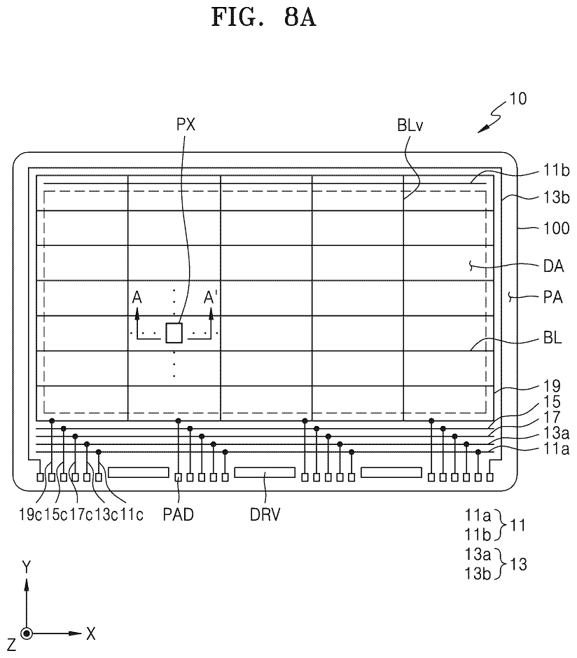

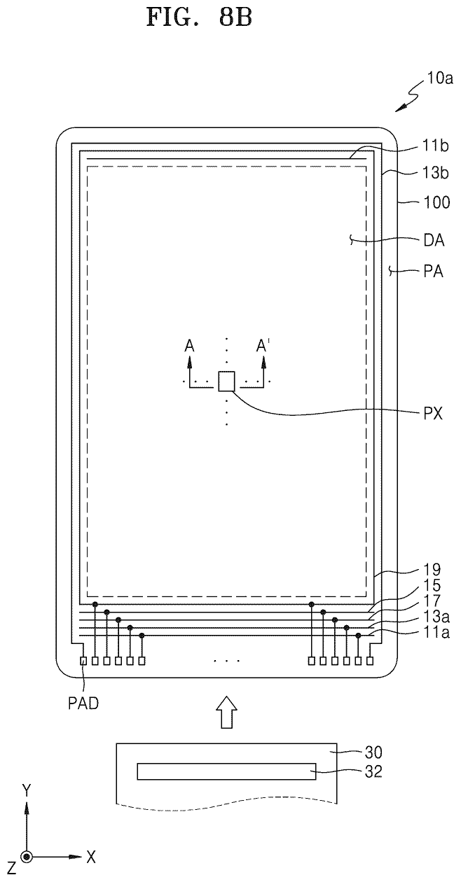

FIGS. 8A and 8B are schematic plan views of a display panel 10 according to an embodiment.

Referring to FIG. 8A, a display device (or an electronic device) may include a display panel 10, and a cover window (not shown) for protecting the display panel 10 and through which an image generated by the display panel 10 is viewable, may be further arranged on the display panel 10.

In a plan view, the display panel 10 may have a rectangular shape as shown in FIG. 8A. Among the two pairs of sides of a rectangle, one pair of sides may be longer than the other pair of sides. In the display panel 10 shown in FIG. 8A, a first direction (X direction, row direction) denotes a direction in which the long side extends, a second direction (Y direction, column direction) denotes a direction in which the short side extends, and a direction perpendicular to the extension directions of the long and short sides is denoted as a third direction (Z direction, e.g., a thickness direction). A least one corner of the display panel 10 may have a round shape.

Referring to FIG. 8A, the display panel 10 may include a display area DA in which a plurality of pixels PX are arranged, and a peripheral area PA which is outside the display area DA. The peripheral area PA may be a non-display area in which pixels PX are not arranged. The display area DA may be entirely surrounded by the peripheral area PA. Various elements constituting the display panel 10 are arranged on a substrate 100. Accordingly, the substrate 100 may be regarded as including the display area DA and the peripheral area PA.

The display panel 10 may provide a certain image by using light emitted from the plurality of pixels PX arranged in the display area DA. A pixel PX may emit, for example, red, green, or blue light. Alternatively, the pixel PX may emit red, green, blue, or white light. The pixel PX may include a display element, and the display element may include an organic light-emitting diode. The display element may be connected to a pixel circuit configured to drive the display element. A certain image may be provided through light emitted from the pixels PX.

Various wires configured to transfer an electrical signal to be applied to the display area DA via the pixel circuit, terminals PAD connected to the wires to transfer a signal applied from the outside of the display panel 10 to the wires, and a driver DRV may be arranged in the peripheral area PA. The various wires configured to transfer an electrical signal may include a driving voltage supply line 11, a common voltage supply line 13, a first initialization voltage supply line 15, a second initialization voltage supply line 17, and a bias voltage supply line 19.

An electrical signal such as a control signal, a test signal, etc. may be received by the display panel 10 at one or more of the terminals PAD. The terminals PAD of the display panel 10 may represent a pad portion at which a testing apparatus is connected to the display panel 10. In an embodiment, the probe terminal portion 23-3 may be connected to the display panel 10 at the terminals PAD thereof. For example, the terminals PAD may be physically exposed to outside the display panel 10 such that an external element like a test apparatus, an electrical component, etc. may be electrically contacted to the terminals PAD.

The driving voltage supply line 11 may include a first driving voltage supply line 11a and a second driving voltage supply line 11b. The common voltage supply line 13 may include a first common voltage supply line 13a and a second common voltage supply line 13b. The first driving voltage supply line 11a may be connected to the terminals PAD through a connection line 11c and may extend in the X direction at a first planar area below the display area DA. The second driving voltage supply line 11b extending in the X direction may be further provided in a second area above the display area DA and opposite to the first planar area. The first common voltage supply line 13a may be connected to the terminals PAD through a connection line 13c and may extend in the X direction below the display area DA. The second common voltage supply line 13b may be connected to the terminals PAD and may have a loop shape with one side open and partially surround the display area DA in the plan view.

The first initialization voltage supply line 15 may be connected to the terminals PAD through a connection line 15c and may extend in the X direction at the first planar area below the display area DA. The second initialization voltage supply line 17 may be connected to the terminals PAD through a connection line 17c and may extend in the X direction at the first planar area below the display area DA. The bias voltage supply line 19 may be connected to the terminals PAD through a connection line 19c and may have a loop shape and surround the display area DA. The bias voltage supply line 19 may be connected to a plurality of bias voltage lines BL and a plurality of vertical bias voltage lines BLv arranged in the display area DA. Accordingly, the bias voltage lines BL may have a mesh structure in the display area DA. In an embodiment, the bias voltage supply line 19 may have a loop shape with an upper side open.

The driver DRV may be in the form of one or more integrated circuit chips and be mounted on the substrate 100. The driver DRV may be configured to generate data signals, and the data signals may be transferred to pixel circuits of pixels PX through data lines of the display area DA. The driver DRV may be configured to generate control signals which are transferred to a scan driving circuit (not shown) arranged in the peripheral area PA. The scan driving circuit may be arranged in the peripheral area PA on the left and/or right side of the substrate 100 with the display area DA therebetween, that is, along the X direction. The scan driving circuit may overlap some of the wires arranged in the peripheral area PA. The scan driving circuit may be configured to generate scan signals, and the scan signals may be transferred to the pixel circuits through scan lines of the display area DA.

Although an organic light-emitting display device is described below as an example of a display device according to an embodiment, a display device described herein is not limited thereto. In an embodiment, the display device described herein may be a display device, such as an inorganic light-emitting display (or an inorganic electroluminescent (EL) display) or a quantum dot light-emitting display. For example, an emission layer of a display element included in the display device may include an organic material or an inorganic material. Alternatively, the display device may include an emission layer, and quantum dots on a path of light emitted from the emission layer.

Referring to FIG. 8B, a display panel 10a shown in FIG. 8B differs from the display panel 10 shown in FIG. 8A in that the second direction (Y direction) has a long side and the first direction (X direction) has a short side in a plan view. A display circuit board 30 on which a display driver 32 is arranged may be connected to one side of the display panel 10a. The display driver 32 may be configured to generate control signals which are transferred to a scan driving circuit (not shown) of the peripheral area PA. The display driver 32 may be configured to generate data signals and transfer the data signals to pixel circuits of the display area DA.

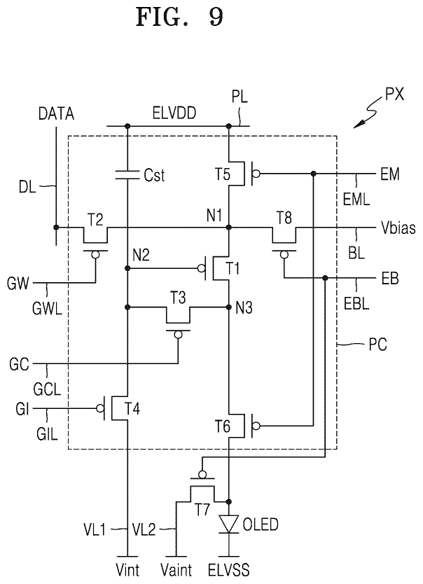

FIG. 9 is an equivalent circuit diagram showing the pixel PX according to an embodiment.

Referring to FIG. 9, the pixel PX includes a pixel circuit PC and an organic light-emitting diode OLED as a display element which is connected to the pixel circuit PC and the common voltage supply line which supply a common voltage ELVSS to the organic light-emitting diode OLED. The pixel circuit PC may include first to eighth transistors T1 to T8, a capacitor Cst, and signal lines connected thereto. The signal lines may include a data line DL, a first gate line GWL, a second gate line GCL, a third gate line GIL, an emission control line EML, a bias control line EBL, first and second initialization voltage lines VL1 and VL2, a driving voltage line PL, and a bias voltage line BL.

The first gate line GWL, the second gate line GCL, the third gate line GIL, the emission control line EML, and the bias control line EBL may be gate control lines to which a gate signal for controlling a transistor to be turned on and turned off is applied. The driving voltage line PL may be configured to transfer a driving voltage ELVDD to the first transistor T1. The driving voltage ELVDD may be a high voltage which is provided to a pixel electrode (a first electrode or an anode) of an organic light-emitting diode included in each pixel PX. The first initialization voltage line VL1 may be configured to transfer a first initialization voltage Vint for initializing the first transistor T1 to the pixel PX. The second initialization voltage line VL2 may be configured to transfer a second initialization voltage Vaint for initializing the organic light-emitting diode OLED to the pixel PX. The bias voltage line BL may be configured to transfer a bias voltage Vbias to the first transistor T1.

The first transistor T1 may be a driving transistor, and the second to eighth transistors T2 to T8 may be switching transistors. Depending on the type (N-type or P-type) and/or operation conditions of a transistor, a first terminal of each of the first to eighth transistors T1 to T8 may be a source terminal or a drain terminal, and a second terminal may be a terminal different from the first terminal. For example, when the first terminal is a source terminal, the second terminal may be a drain terminal. In an embodiment, the source terminal and the drain terminal may be interchangeably referred to as a source electrode and a drain electrode, respectively.

The first transistor T1 may be connected between the driving voltage line PL and the organic light-emitting diode OLED. The first transistor T1 may be connected to the driving voltage line PL via the fifth transistor T5 and may be electrically connected to the organic light-emitting diode OLED via the sixth transistor T6. The first transistor T1 includes a gate connected to a second node N2, a first terminal connected to a first node N1, and a second terminal connected to a third node N3. The first transistor T1 may be configured to receive a data signal according to a switching operation of the second transistor T2 and supply a driving current to the organic light-emitting diode OLED.

The second transistor T2 (data writing transistor) may be connected between the data line DL and the first node N1 and may be connected to the driving voltage line PL via the fifth transistor T5. The first node N1 may be a node to which the first transistor T1 and the fifth transistor T5 are connected. The second transistor T2 includes a gate connected to the first gate line GWL, a first terminal connected to the data line DL, and a second terminal connected to the first node N1 (or the first terminal of the first transistor T1). The second transistor T2 may be turned on according to a first gate signal GW received through the first gate line GWL to perform a switching operation for transmitting a data signal transferred through the data line DL to the first node N1.

The third transistor T3 (compensation transistor) may be connected between the second node N2 and the third node N3. The third transistor T3 may be connected to the organic light-emitting diode OLED via the sixth transistor T6. The second node N2 may be a node to which the gate of the first transistor T1 is connected, and the third node N3 may be a node to which the first transistor T1 and the sixth transistor T6 are connected. The third transistor T3 includes a gate connected to the second gate line GCL, a first terminal connected to the second node N2 (or the gate of the first transistor T1), and a second terminal connected to the third node N3 (or the second terminal of the first transistor T1). The third transistor T3 may be turned on according to a second gate signal GC received through the second gate line GCL to diode-connect the first transistor T1, thereby compensating for a threshold voltage of the first transistor T1.

The fourth transistor T4 (first initialization transistor) may be connected between the second node N2 and the first initialization voltage line VL1. The fourth transistor T4 includes a gate connected to the third gate line GIL, a first terminal connected to the second node N2, and a second terminal connected to the first initialization voltage line VL1. The fourth transistor T4 may be turned on according to a third gate signal GI received through the third gate line GIL to transfer the first initialization voltage Vint to the gate of the first transistor T1 and initialize the gate of the first transistor T1.

The fifth transistor T5 (first emission control transistor) may be connected between the driving voltage line PL and the first node N1. The sixth transistor T6 (second emission control transistor) may be connected between the third node N3 and the organic light-emitting diode OLED. The fifth transistor T5 includes a gate connected to the emission control line EML, a first terminal connected to the driving voltage line PL, and a second terminal connected to the first node N1. The sixth transistor T6 includes a gate connected to the emission control line EML, a first terminal connected to the third node N3, and a second terminal connected to a pixel electrode of the organic light-emitting diode OLED. The fifth transistor T5 and the sixth transistor T6 are simultaneously turned on according to an emission control signal EM received through the emission control line EML, and thus, a driving current flows through the organic light-emitting diode OLED.

The seventh transistor T7 (second initialization transistor) may be connected between the organic light-emitting diode OLED and the second initialization voltage line VL2. The seventh transistor T7 may include a gate connected to the bias control line EBL, a first terminal connected to the second terminal of the sixth transistor T6 and the pixel electrode of the organic light-emitting diode OLED, and a second terminal connected to the second initialization voltage line VL2. The seventh transistor T7 may be turned on according to a bias control signal EB received through the bias control line EBL to transfer the second initialization voltage Vaint to the pixel electrode of the organic light-emitting diode OLED and initialize the pixel electrode of the organic light-emitting diode OLED. The seventh transistor T7 may be omitted.

The eighth transistor T8 (bias transistor) may be connected between the first node N1 and the bias voltage line BL. The eighth transistor T8 may include a gate connected to the bias control line EBL, a first terminal connected to the bias voltage line BL, and a second terminal connected to the first node N1. The eighth transistor T8 may be turned on according to the bias control signal EB received through the bias control line EBL to apply the bias voltage Vbias to the first terminal of the first transistor T1 and preset the first terminal to a voltage which is suitable for a subsequent operation of the first transistor T1.

In FIG. 9, the pixel circuit PC is shown in which the first to eighth transistors T1 to T8 are implemented as p-channel MOSFETs (PMOS), but one or more embodiments are not limited thereto. In the pixel circuit PC, the third transistor T3 and the fourth transistor T4 among the first to eighth transistors T1 to T8 may be implemented as n-channel MOSFETs (NMOS) and the rest may be implemented as p-channel MOSFETs (PMOS).

The apparatus 20 for manufacturing a display device may measure at least one of a transfer curve, hysteresis, a leakage current, and a driving range of the first transistor T1. In particular, the apparatus 20 for manufacturing a display device may detect a defect in the display panel 10 through a color deviation test and an afterimage test by measuring a current for each driving range section of the first transistor T1.

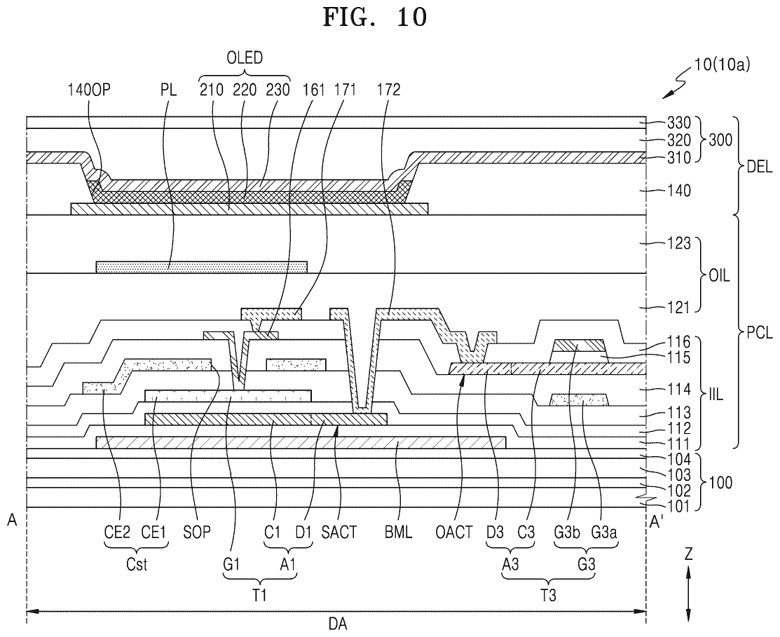

FIG. 10 is a cross-sectional view of the display panel 10 or 10A taken along a line A-A′ of FIG. 8A or 8B, respectively.

Referring to FIG. 10, the display panel 10 or 10A may include the substrate 100, a pixel circuit layer PCL, and a light-emitting diode layer DEL as a display element layer.

Elements within the pixel circuit layer PCL may define a pixel circuit. The pixel circuit layer PCL may include elements of transistors and capacitors, and insulating layers arranged under and/or over the elements. In this regard, FIG. 10 shows the first transistor T1, the third transistor T3, and a first capacitor Cst among transistors and capacitors included in the pixel circuit. In addition, the pixel circuit layer PCL may include inorganic insulating layers IIL and organic insulating layers OIL. For example, as shown in FIG. 10, the inorganic insulating layers IIL may include a buffer layer 111, a first gate insulating layer 112, a first interlayer insulating layer 113, a second interlayer insulating layer 114, a second gate insulating layer 115, and a third interlayer insulating layer 116. The organic insulating layers OIL may include a first organic insulating layer 121 and a second organic insulating layer 123.

The substrate 100 may include a glass material, a ceramic material, a metal material, plastic, or a flexible or bendable material. When the substrate 100 is flexible or bendable, the substrate 100 may include polymer resin, such as polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), cellulose acetate propionate (CAP), etc.

The substrate 100 may have a single-layer structure or multi-layer structure including the above material. In the multi-layer structure, the substrate 100 may further include an inorganic layer. For example, the substrate 100 may include a first organic base layer 101, a first inorganic barrier layer 102, a second organic base layer 103, and a second inorganic barrier layer 104. Each of the first organic base layer 101 and the second organic base layer 103 may include polymer resin. The first inorganic barrier layer 102 and the second inorganic barrier layer 104 are barrier layers which prevent penetration of an external foreign material and may include a single layer or a plurality of layers including an inorganic insulating material such as silicon nitride and/or silicon oxide.

A bottom metal layer BML may be arranged on the substrate 100. The bottom metal layer BML may include one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, the bottom metal layer BML may include a single molybdenum layer, may have a two-layer structure in which a molybdenum layer and a titanium layer are stacked, or may have a three-layer structure in which a titanium layer, an aluminum layer, and a titanium layer are stacked.

The buffer layer 111 may be arranged over the bottom metal layer BML. The buffer layer 111 may be an inorganic insulating layer including an inorganic insulating material such as silicon nitride and/or silicon oxide and may have a single-layer or multi-layer structure including the above material.

Silicon semiconductor layers of silicon-based transistors may be arranged on the buffer layer 111. In this regard, FIG. 10 shows a semiconductor layer A1 of the first transistor T1 corresponding to a portion of a silicon semiconductor pattern SACT. The semiconductor layer A1 may include a channel region C1 and impurity regions arranged on both sides of the channel region C1 and doped with an impurity, and FIG. 10 shows a second region D1, which is one of the impurity regions arranged on one side of the channel region C1.

The first gate insulating layer 112 may be arranged over the silicon semiconductor pattern SACT. The first gate insulating layer 112 may be an inorganic insulating layer including an inorganic insulating material such as silicon oxide, silicon nitride and/or silicon oxynitride and may have a single-layer or multi-layer structure including the above material.

A gate electrode G1 and a first capacitor electrode CE1 may be arranged on the first gate insulating layer 112. FIG. 10 shows the gate electrode G1 integrally formed into a single, continuous body with the first capacitor electrode CE1. In other words, the gate electrode G1 may serve as the first capacitor electrode CE1, or the first capacitor electrode CE1 may serve as the gate electrode G1.

The gate electrode G1 and/or the first capacitor electrode CE1 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and/or copper (Cu) and may include a single layer or a plurality of layers including the above material.

The first interlayer insulating layer 113 may be arranged over the gate electrode G1 and/or the first capacitor electrode CE1. The first interlayer insulating layer 113 may be an inorganic insulating layer including an inorganic insulating material such as silicon oxide, silicon nitride and/or silicon oxynitride and may have a single-layer or multi-layer structure including the above material.

A second capacitor electrode CE2 may be arranged on the first interlayer insulating layer 113. The second capacitor electrode CE2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and/or copper (Cu) and may include a single layer or a plurality of layers including the above material. The second capacitor electrode CE2 may overlap the gate electrode G1 and/or the first capacitor electrode CE1. The second capacitor electrode CE2 may include an opening SOP so that a connection electrode 161 electrically connected to a first end a first connection electrode 171 may be further connected to the gate electrode G1. The opening SOP may overlap a portion of the gate electrode G1. Although not shown, another end of the first connection electrode 171 may be electrically connected to a source region of the third transistor T3.

The second interlayer insulating layer 114 may be arranged over the second capacitor electrode CE2. The second interlayer insulating layer 114 may be an inorganic insulating layer including an inorganic insulating material such as silicon oxide, silicon nitride and/or silicon oxynitride and may have a single-layer or multi-layer structure including the above material.

Oxide semiconductor layers may be arranged on the second interlayer insulating layer 114. In this regard, FIG. 10 shows a semiconductor layer A3 of the third transistor T3 corresponding to a portion of an oxide semiconductor pattern OACT. The semiconductor layer A3 may include a channel region C3 and conductive regions arranged on both sides of the channel region C3, and FIG. 10 shows a second region D3, which is one of the conductive regions arranged on one side of the channel region C3. A vertical distance from the substrate 100 to the semiconductor layer A3 may be greater than a vertical distance from the substrate 100 to the semiconductor layer A1. That is, the semiconductor layer A3 may be further from the substrate 100 than the semiconductor layer A1, along a thickness direction of the display panel 10

A gate electrode G3 may include portions respectively arranged below and/or above the semiconductor layer A3. FIG. 10 shows the gate electrode G3 including a bottom gate electrode G3a arranged under the semiconductor layer A3 and a top gate electrode G3b arranged over the semiconductor layer A3. In an embodiment, one of the bottom gate electrode G3a and the top gate electrode G3b may be omitted.

The bottom gate electrode G3a may include the same material as that of the second capacitor electrode CE2 and may be arranged on a layer (e.g., the first interlayer insulating layer 113) on which the second capacitor electrode CE2 is arranged. That is, the bottom gate electrode G3a and the second capacitor electrode CE2 may be in a same layer. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The top gate electrode G3b may be arranged over the semiconductor layer A3 with the second gate insulating layer 115 therebetween. The top gate electrode G3b may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and/or copper (Cu) and may include a single layer or a plurality of layers including the above material.

FIG. 10 shows the second gate insulating layer 115 as a pattern arranged only between the top gate electrode G3b and the semiconductor layer A3, but one or more embodiments are not limited thereto. In an embodiment, the second gate insulating layer 115 may entirely cover the substrate 100 as another insulating layer, for example, the first gate insulating layer 112, does. The second gate insulating layer 115 may be an inorganic insulating layer including an inorganic insulating material such as silicon oxide, silicon nitride and/or silicon oxynitride and may have a single-layer or multi-layer structure including the above material.

The third interlayer insulating layer 116 may be arranged over the top gate electrode G3b and the connection electrode 161. The third interlayer insulating layer 116 may be an inorganic insulating layer including an inorganic insulating material such as silicon oxide, silicon nitride and/or silicon oxynitride and may have a single-layer or multi-layer structure including the above material.

The first connection electrode 171 and a second connection electrode 172 may be arranged on the third interlayer insulating layer 116. The first connection electrode 171 and the second connection electrode 172 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and/or copper (Cu) and may include a single layer or a plurality of layers including the above material. For example, the first connection electrode 171 and the second connection electrode 172 may include a three-layer structure in which a titanium layer, an aluminum layer, and a titanium layer are stacked.

The second connection electrode 172 may electrically connect the semiconductor layer A1 and the semiconductor layer A3 to each other. The second connection electrode 172 may be connected to a portion (e.g., the second region D1 of FIG. 10) of the semiconductor layer A1 through a contact hole penetrating inorganic insulating layers arranged between the semiconductor layer A1 and the second connection electrode 172, for example, the first gate insulating layer 112, the first interlayer insulating layer 113, the second interlayer insulating layer 114, and the third interlayer insulating layer 116. The second connection electrode 172 may be connected to a portion (e.g., the second region D3 of FIG. 10) of the semiconductor layer A3 through a contact hole penetrating the third interlayer insulating layer 116 arranged between the semiconductor layer A3 and the second connection electrode 172.

The bottom metal layer BML may have a voltage level of a constant voltage. The bottom metal layer BML may prevent or reduce the occurrence of an afterimage due to (−) charges by preventing the (−) charges from gathering at a lower portion of the first semiconductor layer A1 of the first transistor T1.

The first organic insulating layer 121 may be formed over the second connection electrode 172 and the first connection electrode 171. The first organic insulating layer 121 may include an organic material, such as acryl, benzocyclobutene (BCB), polyimide, or hexamethyldisiloxane (HMDSO).

A first power voltage line PL may be arranged on the first organic insulating layer 121. The second organic insulating layer 123 may be arranged over the first power voltage line PL. The first power voltage line PL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti) and/or tungsten (W). In some embodiments, the first power voltage line PL may include a three-layer structure of a titanium layer, an aluminum layer, and a titanium layer.

The second organic insulating layer 123 may include an organic material, such as benzocyclobutene (BCB), polyimide, or hexamethyldisiloxane (HMDSO).

The light-emitting diode layer DEL may be arranged on the pixel circuit layer PCL. The light-emitting diode layer DEL may include a light-emitting diode. For example, the light-emitting diode layer DEL may include the organic light-emitting diode OLED. The organic light-emitting diode OLED may include a pixel electrode 210, an emission layer 220, and an opposite electrode 230.

The pixel electrode 210 of the organic light-emitting diode OLED may be on the second organic insulating layer 123. The emission layer 220 may include a low-molecular weight organic material or a polymer organic material. At least one layer selected from among a hole injection layer (HIL), a hole transport layer (HTL), an electron transport layer (ETL), and an electron injection layer (EIL) may be further arranged between the pixel electrode 210 and the opposite electrode 230.

Edges of the pixel electrode 210 may be covered by solid material portions of a bank layer 140, and an inner portion of the pixel electrode 210 may overlap the emission layer 220 through an opening 140OP of the bank layer 140. While the pixel electrode 210 is formed (or provided) for each organic light-emitting diode OLED, respectively, the opposite electrode 230 may be formed in correspondence with a plurality of organic light-emitting diodes OLED. In other words, the plurality of organic light-emitting diodes OLED may share the opposite electrode 230, and a stacked structure of the pixel electrode 210, the emission layer 220, and a portion of the opposite electrode 230 may correspond to the organic light-emitting diode OLED.

An encapsulation layer 300 may be arranged over the organic light-emitting diode OLED. The encapsulation layer 300 may include at least one inorganic encapsulation layer and at least one organic encapsulation layer. FIG. 10 shows an embodiment in which the encapsulation layer 300 includes a first inorganic encapsulation layer 310, an organic encapsulation layer 320, and a second inorganic encapsulation layer 330. The first inorganic encapsulation layer 310 and the second inorganic encapsulation layer 330 may include silicon oxide, silicon nitride and/or silicon oxynitride, and the organic encapsulation layer 320 may include an organic insulating material.

The display panel 10 or 10a may be applied to various electronic devices (or display modules or display devices). An electronic device according to an embodiment of the present disclosure may include the display panel 10 or 10a described above, and may further include a module or device having additional functions in addition to the display panel 10 or 10a.

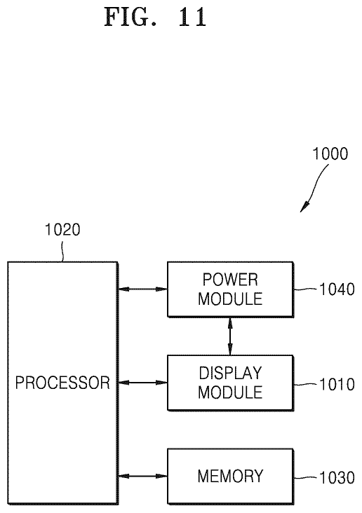

FIG. 11 is a block diagram illustrating an electronic device according to an embodiment of the present disclosure.

Referring to FIG. 11, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module which converts power supplied by the power supply module to generate power necessary for an operation of the electronic device 1000.

At least one of the components of the electronic device 1000 described above may be included in the display device (or display panel) according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

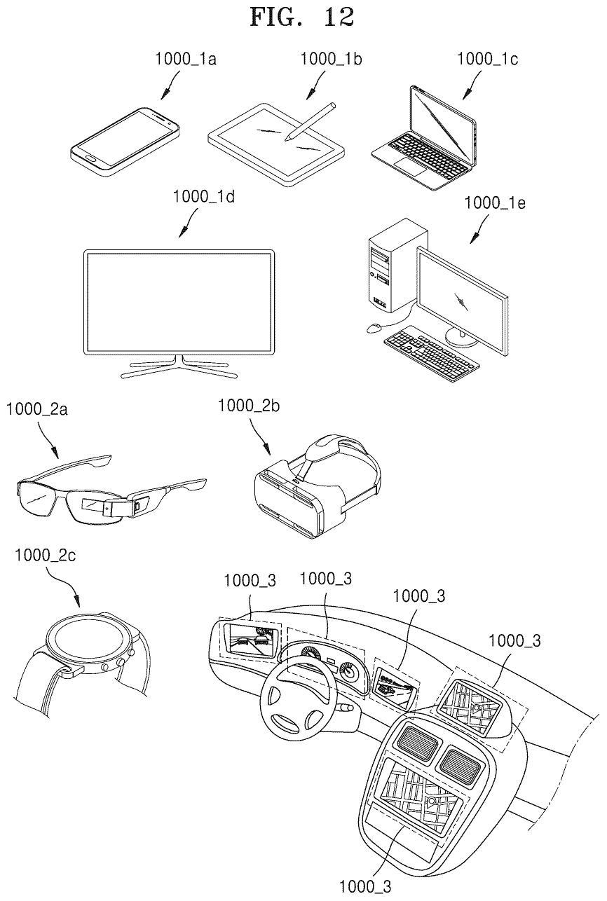

FIG. 12 is a schematic view of electronic devices according to embodiments of the present disclosure.

Referring to FIG. 12, various electronic devices to which the display device according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

A method and an apparatus 20 for manufacturing (or providing) a display device according to one or more of the above embodiments may allow the operation of a display device to be precisely tested.

A testing method and a testing apparatus for manufacturing (or providing) a display device according to one or more of the above embodiments may allow detection of an electrical signal with reduced electrical noise.

In an embodiment, a method of providing an electronic device includes providing electrical signals from a circuit board to a display panel 10 and providing electrical signals generated by the display panel 10 to the circuit board, and transmitting a first electrical signal and a second electrical signal between the display panel 10 and the circuit board, through a first wire of a first connection member 22-1 and a second wire of a second connection member 22-2, respectively. Here, the first connection member 22-1, the second connection member 22-2 and the circuit board overlap each other along a thickness direction of the circuit board to define an overlapping area, and within the overlapping area, the first wire and the second wire are non-overlapping.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for providing an electronic device, the apparatus comprising:
a connection portion comprising terminals at which the apparatus is connected to a display panel of the electronic device;
a circuit board from which an electrical signal is provided to the display panel and to which an electrical signal generated from the display panel is provided; and
connection members each electrically connecting the connection portion to the circuit board, the connection members comprising:
a first connection member comprising a first wire through which a first electrical signal passes between the connection portion and the circuit board; and
a second connection member comprising a second wire through which a second electrical signal passes between the connection portion and the circuit board,
wherein
the first connection member and the second connection member overlap each other along a thickness direction of the circuit board to define an overlapping area, and
within the overlapping area, the first wire and the second wire are non-overlapping.

2. The apparatus of claim 1, wherein
the connection members each extend in a first direction from the connection portion to the circuit board, and
in a second direction which crosses the first direction, a width of the first connection member is greater than a width of the second connection member.

3. The apparatus of claim 1, wherein
the first electrical signal includes alternating electrical current, and
the second electrical signal includes direct electrical current.

4. The apparatus of claim 1, wherein
the connection members each extend in a first direction from the connection portion to the circuit board, and
a width of the first connection member in a second direction which crosses the first direction varies along the first direction of the first connection member.

5. The apparatus of claim 1, wherein the first wire is bent along a length direction of the first connection member.

6. The apparatus of claim 1, wherein the first wire comprises:
a 1st-1 wire portion inclined in a direction away from a center of the first connection member;
a 1st-2 wire portion extended from the 1st-1 wire portion and parallel to a length direction of the first connection member; and
a 1st-3 wire portion extended from the 1st-2 wire portion and inclined in a different direction from the 1st-1 wire portion.

7. The apparatus of claim 1, wherein the first connection member comprises:
the first wire provided in plural including first wires, and
an opening which is defined in the first connection member and between the first wires.

8. The apparatus of claim 1, wherein the first connection member comprises:
the first wire provided in plural including first wires at opposing sides of the first connection member, and
the second wire between the first wires.

9. The apparatus of claim 1, wherein the second connection member comprises:
the second wire provided in plural including second wires, and
a distance between the second wires which is equal to or greater than about 20 micrometers.

10. The apparatus of claim 1, wherein along the thickness direction, the first connection member comprises a shield layer between the second connection member and a remaining thickness portion of the first connection member.

11. A method of providing an electronic device, the method comprising:
providing electrical signals from a circuit board to a display panel and providing electrical signals generated by the display panel to the circuit board;
transmitting a first electrical signal and a second electrical signal between the display panel and the circuit board, through a first wire of a first connection member and a second wire of a second connection member, respectively,
wherein
the first connection member and the second connection member overlap each other along a thickness direction of the circuit board to define an overlapping area, and within the overlapping area, the first wire and the second wire are non-overlapping.

12. The method of claim 11, wherein
each of the first connection member and the second connection member has a planar shape including a length from the circuit board to the display panel and a width which is smaller than the length, and
a width of the first connection member is greater than a width of the second connection member.

13. The method of claim 11, wherein
the first electrical signal includes alternating electrical current, and
the second electrical signal includes direct electrical current.

14. The method of claim 11, wherein
the first connection member has a planar shape including a length from the circuit board to the display panel and a width which is smaller than the length, and
a width of the first connection member varies along the length of the first connection member.

15. The method of claim 11, wherein the first wire is bent along a length direction of the first connection member.

16. The method of claim 11, wherein the first wire comprises:
a 1st-1 wire portion inclined in a direction away from a center of the first connection member;
a 1st-2 wire portion extended from the 1st-1 wire portion and arranged parallel to a length direction of the first connection member; and
a 1st-3 wire portion extended from the 1st-2 wire portion and inclined in a different direction from the 1st-1 wire portion.

17. The method of claim 11, wherein the first connection member comprises:
the first wire provided in plural including first wires, and
an opening which is defined in the first connection member and between the first wires.

18. The method of claim 11, wherein the first connection member comprises:
the first wire provided in plural including first wires at opposing sides of the first connection member, and
the second wire between the first wires.

19. The method of claim 11, wherein the second connection member comprises:
the second wire provided in plural including second wires, and
a distance between the second wires which is equal to or greater than about 20 micrometers.

20. The method of claim 11, wherein along the thickness direction, the first connection member comprises a shield layer between the second connection member and a remaining thickness portion of the first connection member.
